(19) United States
(12) Patent Application Publication
(10) Pub. No.: US 2019/0214087 A1
(43) Pub. Date: Jul. 11, 2019

(54) NON-VOLATILE STORAGE SYSTEM WITH DECOUPLING OF WRITE TRANSFERS FROM WRITE OPERATIONS

(71) Applicant: Western Digital Technologies, Inc., San Jose, CA (US)

(72) Inventors: Yoav Weinberg, Thornhill (CA); Grishma Shah, Milpitas, CA (US)

(73) Assignee: Western Digital Technologies, Inc., San Jose, CA (US)

(21) Appl. No.: 15/865,618

(22) Filed: Jan. 9, 2018

(51) Int. Cl. G11C 16/10; G11C 16/26; G11C 7/10; G06F 3/06; G06F 12/02

(52) U.S. Cl. CPC G11C 16/10; G11C 16/26; G06F 12/0246; G06F 3/0659; G06F 3/0679; G11C 7/1087

(57) ABSTRACT

A non-volatile memory system implements the writing of data by decoupling the write transfer and the write operation. One embodiment includes setting up a write operation for a first memory die to write to a first address and performing a data transfer to the first memory die for the write operation in response to the determining that sufficient resources exist to perform a data transfer. The first memory die is subsequently released from the write operation without the first memory die writing the transferred data so that the first memory die is in an idle state. In response to determining that sufficient resources exist to perform the write operation, the first memory die is instructed to write the transferred data to the first address in non-volatile memory on the first memory die without re-transferring the data.

### BACKGROUND

Semiconductor memory is widely used in various electronic devices such as cellular telephones, digital cameras, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery). An apparatus that includes a memory system, or is connected to a memory system, is often referred to as a host.

Memory systems that interface with a host are required to limit power consumption and thermal dissipation to meet both host and memory system constraints. The power and thermal limits are required to ensure that the power supply regulators provided by the host are not overloaded by excess current, the power supply regulators included with the memory system are not overloaded by excess current, batteries associated with the host are drained at a rate that is acceptable to the end customer, and the temperature of the system (including the host, memory and all associated components) are maintained within valid operating ranges.

### BRIEF DESCRIPTION OF THE DRAWINGS

Like-numbered elements refer to common components in the different figures.

FIG. 1 is a block diagram of one embodiment of a memory system connected to a host.

FIG. 2 is a block diagram of one embodiment of a Front End Processor Circuit. The Front End Processor Circuit is part of a controller.

FIG. 3 is a block diagram of one embodiment of a Back End Processor Circuit. In some embodiments, the Back End Processor Circuit is part of a controller.

FIG. 4 is a block diagram of one embodiment of a memory package.

FIG. 5 is a block diagram of one embodiment of a memory die.

FIG. 6 is a logical block diagram of components running on the controller.

FIG. 7 is a flow chart describing one embodiment of a process for implementing a write to memory that decouples the write transfer and the write operation.

FIGS. 8A, 8B, 9A and 9B are signal diagrams depicting the behavior of the chip enable signal and the bus signals for an interface between a controller and a memory die.

FIG. 10 is a flow chart describing one embodiment of a process for implementing a write to memory that decouples the write transfer and the write operation.

FIG. 11 is a flow chart describing one embodiment of a process for implementing a write to memory that decouples the write transfer and the write operation.

FIG. 12 is a flow chart describing one embodiment of a process for implementing a write to memory that decouples the write transfer and the write operation.

FIGS. 13A and 13B together depict a flow chart describing one embodiment of a process for implementing a write to memory that decouples the write transfer and the write operation.

FIG. 14 is a flow chart describing one embodiment of a process for implementing a write to memory that decouples the write transfer and the write operation.

FIGS. 15A and 15B together depict a flow chart describing one embodiment of a process performed by an Arbiter to decouple the write transfer and the write operation.

### DETAILED DESCRIPTION

When data is written to a memory die, it is often done so using multiple stages combined together into a single atomic sequence. In each stage of the write operation, power is consumed in a manner that impact different limits relative to other stages of the write. In the first stage (also known as the write transfer), the controller transfers data to the latches on the memory die by toggling bus signals, consuming power from the regulator responsible for supplying the memory I/O voltage supply. In the second stage (the actual write operation), the memory die consumes power from its core supply by programming data from its latches into its non-volatile memory cells. During both stages of the write operation, power is consumed from the host provided supply and heat is dissipated. Each scheduled write must ensure that the power consumption of memory die I/O supply does not exceed its defined limits during the data transfer stage, that the power consumption of the memory die core supply does not exceed its defined limits during the programming stage, and that the host power consumption limit and thermal dissipation limits are not exceeded throughout both steps.

High performance memory systems include one or more controllers that connect to multiple memory dies that are each capable of performing an independent set of operations. For example, one memory die may be performing a write operation while other memory dies are busy performing erase or read operations. The controller is responsible for maximizing the system performance by ensuring that operations are scheduled as efficiently as possible by maximizing the workload of available memory dies while meeting the host and device specified power consumption and heat dissipation limits.

A non-volatile memory system is proposed that implements the writing of data by decoupling the write transfer and the write operation. This proposal enables more concurrent operations to be issued to the same or other memory dies, and improves the overall performance of the system when constrained by power consumption or thermal limits.

In one set of embodiments, a memory system includes a plurality of memory dies connected to a controller. The controller is configured to send a command to the first memory die to set up a write operation on the first memory die and transfer data for the write operation to the first memory die. The controller release the first memory die from the write operation without the first memory die performing the write operation so that the first memory die can process other commands or the controller can perform commands with other memory dies. Subsequent to releasing the first memory die from the write operation, the controller sends a command to the first memory die to perform the write operation. The first memory die writes the transferred data to non-volatile memory on the first memory die in response to the command to perform the write operation.

In some embodiments, the decoupling of the write transfer and the write operation provides for more efficient use of memory system resources and higher performance. For example, one embodiment includes setting up a write operation for a first memory die to write to a first address in non-volatile memory on the first memory die and performing a data transfer to the first memory die for the write operation in response to the determining that sufficient power resources (or thermal budget) exist to perform a data transfer. The first memory die is subsequently released from the write operation without the first memory die writing the transferred data to the first address in non-volatile memory on the first memory die so that the first memory die is in an idle state. In response to determining that sufficient power resources (or thermal budget) exist to perform the write operation, the first memory die is instructed to write the transferred data to the first address in non-volatile memory on the first memory die without re-transferring the data.

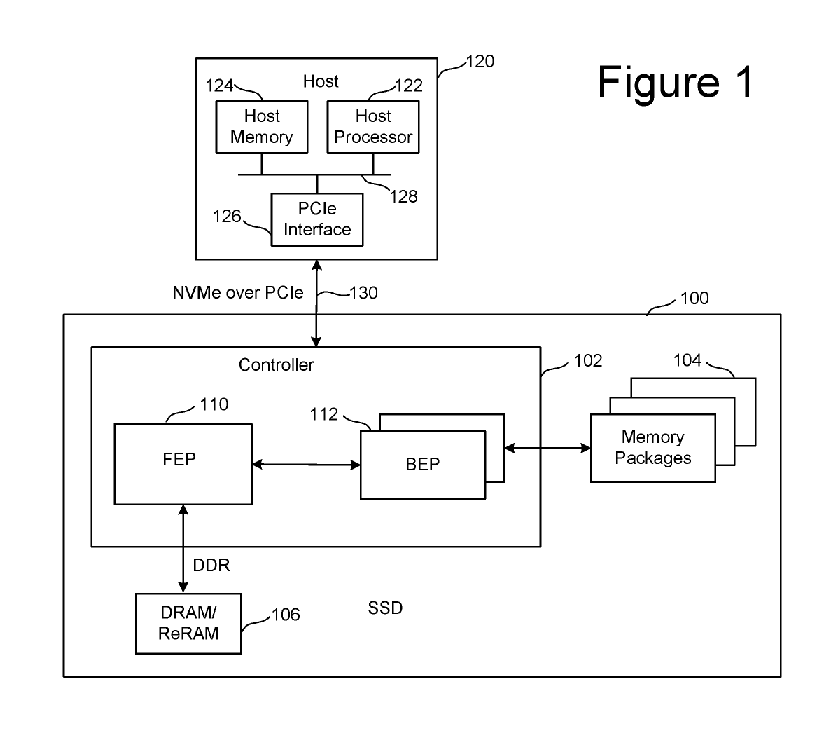

FIG. 1 is a block diagram of one embodiment of a memory system 100 connected to a host 120. Memory system 100 implements the technology proposed herein. Many different memory systems can be used with the technology proposed herein. One example memory system is a solid state drive (“SSD”). Memory system 100 comprises a controller 102, non-volatile memory 104 for storing data, and local memory (e.g. DRAM/ReRAM) 106. Controller 102 comprises a Front End Processor Circuit (FEP) 110 and one or more Back End Processor Circuits (BEP) 112. In one embodiment the FEP110 circuit is implemented on an ASIC. In one embodiment, each BEP circuit 112 is implemented on a separate ASIC. The ASICs for each of the BEP circuits 112 and the FEP circuit 110 are implemented on the same semiconductor such that the controller 102 is manufactured as a System on a Chip (“SoC”). FEP 110 and BEP 112 both include their own processors. In one embodiment, FEP110 and BEP 112 work as a master slave configuration where the FEP110 is the master and each BEP 112 is a slave. For example, FEP circuit 110 implements a flash translation layer, including performing memory management (e.g., garbage collection, wear leveling, etc.), logical to physical address translation, communication with the host, management of DRAM (local volatile memory) and management the overall operation of the SSD (or other non-volatile storage system). The BEP circuit 112 manages memory operations in the memory packages/die at the request of FEP circuit 110. For example, the BEP circuit 112 can carry out the read, erase and programming processes. Additionally, the BEP circuit 112 can perform buffer management, set specific voltage levels required by the FEP circuit 110, perform error correction (ECC), control the Toggle Mode interfaces to the memory packages, etc. In one embodiment, each BEP circuit 112 is responsible for its own set of memory packages.

In one embodiment, non-volatile memory 104 comprises a plurality of memory packages. Each memory package includes one or more memory die. Therefore, controller 102 is connected to one or more non-volatile memory die. In one embodiment, the memory die in the memory packages 14 utilize NAND flash memory (including two dimensional NAND flash memory and/or three dimensional NAND flash memory). In other embodiments, the memory package can include other types of memory.

Controller 102 communicates with host 120 via an interface 130 that implements NVMe over PCIe. For working with memory system 100, host 120 includes a host processor 122, host memory 124, and a PCIe interface 126. Host memory 124 is the host's physical memory, and can be DRAM, SRAM, non-volatile memory or another type of storage. Host 120 is external to and separate from memory system 100 (e.g., an SSD). In one embodiment, memory system 100 is embedded in host 120.

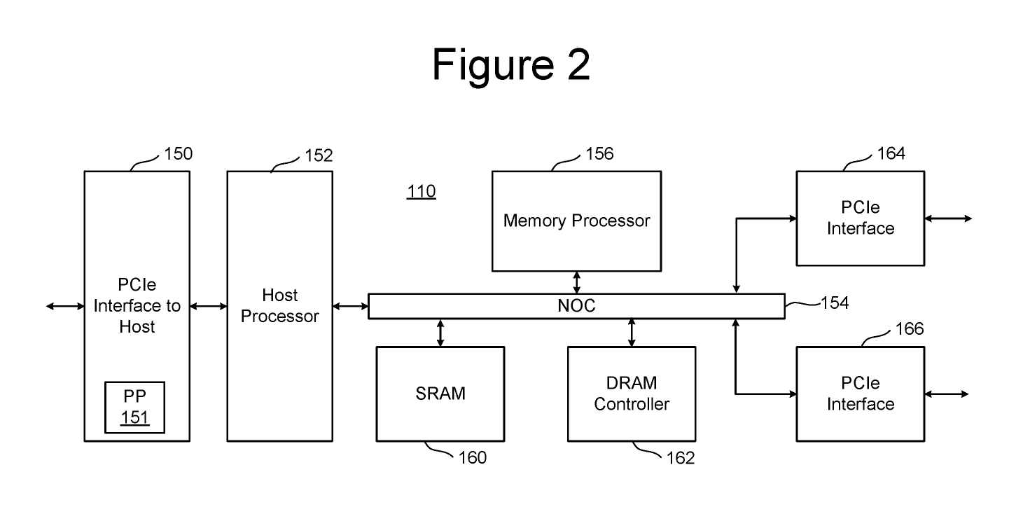

FIG. 2 is a block diagram of one embodiment of an FEP circuit 110. FIG. 2 shows a PCIe interface 150 to communicate with the host and a host processor 152 in communication with that PCIe interface. The host processor 152 can be any type of processor known in the art that is suitable for the implementation. Host processor 152 is in communication with a network-on-chip (NOC) 154. An NOC is a communication subsystem on an integrated circuit, typically between cores in a SoC. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of SoCs and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, an NOC provides enhanced performance (such as throughput) and scalability in comparison with previous communication architectures (e.g., dedicated point-to-point signal wires, shared buses, or segmented buses with bridges). Connected to and in communication with NOC 154 is the memory processor 156, SRAM 160 and a DRAM controller 162. The DRAM controller 162 is used to operate and communicate with the DRAM (e.g., DRAM 106). SRAM 160 is local RAM memory used by memory processor 156. Memory processor 156 is used to run the FEP circuit and perform the various memory operations. Also in communication with the NOC are two PCIe Interfaces 164 and 166. In the embodiment of FIG. 2, the SSD controller will include two BEP circuits 112; therefore there are two PCIe Interfaces 164/166. Each PCIe Interface communicates with one of the BEP circuits 112. In other embodiments, there can be more or less than two BEP circuits 112; therefore, there can be more than two PCIe Interfaces.

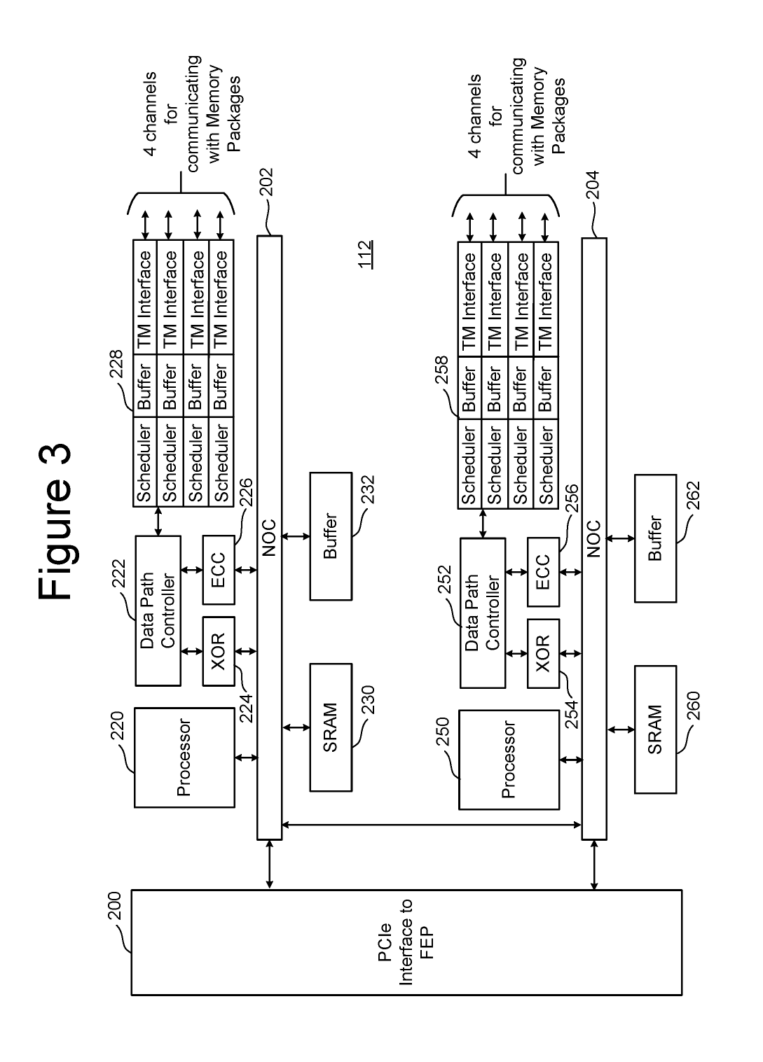

FIG. 3 is a block diagram of one embodiment of the BEP circuit 112. FIG. 3 shows a PCIe Interface 200 for communicating with the FEP circuit 110 (e.g., communicating with one of PCIe Interfaces 164 and 166 of FIG. 2). PCIe Interface 200 is in communication with two NOCs 202 and 204. In one embodiment the two NOCs can be combined to one large NOC. Each NOC (202/204) is connected to SRAM (230/260), a buffer (232/262), processor (220/250), and a data path controller (222/252) via an XOR engine (224/254) and an ECC engine (226/256). The ECC engines 226/256 are used to perform error correction, as known in the art. The XOR engines 224/254 are used to XOR the data so that data can be combined and stored in a manner that can be recovered in case there is a programming error. The data path controller is connected to an interface module for communicating via four channels with memory packages. Thus, the top NOC 202 is associated with an interface 228 for four channels for communicating with memory packages and the bottom NOC 204 is associated with an interface 258 for four additional channels for communicating with memory packages. Each interface 228/258 includes four Toggle Mode interfaces (TM Interface), four buffers and four schedulers. There is one scheduler, buffer and TM Interface for each of the channels. The processor can be any standard processor known in the art. The data path controllers 222/252 can be a processor, FPGA, microprocessor or other type of controller. The XOR engines 224/254 and ECC engines 226/256 are dedicated hardware circuits, known as hardware accelerators. In other embodiments, the XOR engines 224/254 and ECC engines 226/256 can be implemented in software. The scheduler, buffer, and TM Interfaces are hardware circuits.

In another embodiment, there is no PCIe interface between FEP circuit 110 and BEP circuit 112. Rather, FEP circuit 110 and BEP circuit 112 are connected through a common NOC.

The table below provides a definition of one example of Toggle Mode Interface.

TABLE 1

| Signal Name | Type | Function |
|---|---|---|
| ALE | Input | Address Latch Enable controls the activating path for |
| | | addresses to the internal address registers. Addresses are |
| | | latched on the rising edge of WEn with ALE high. |
| CEn | | Chip Enable controls memory die selection. |
| CLE | Input | Command Latch Enable controls the activating path for |
| | | commands sent to the command register. When active |
| | | high, commands are latched into the command register |
| | | through the I/O ports on the rising edge of the WEn |
| | | signal. |
| RE | Input | Read Enable Complement |
| REn | Input | Read Enable controls serial data out, and when active, |
| | | drives the data onto the I/O bus. |
| WEn | Input | Write Enable controls writes to the I/O port. Commands |
| | | and addresses are latched on the rising edge of the WEn |
| | | pulse. |
| WPn | Input | Write Protect provides inadvertent program/erase |
| | | protection during power transitions. The internal high |
| | | voltage generator is reset when the WPn pin is active |
| | | low. |
| DQS | Input/Output | Data Strobe acts as an output when reading data, and as |
| | | an input when writing data. DQS is edge-aligned with |
| | | data read; it is center-aligned with data written. |
| DQSn | Input/Output | Data Strobe complement (used for DDR) |
| Bus[0:7] | Input/Output | Data Input/Output (I/O) bus inputs commands, |
| | | addresses, and data, and outputs data during Read |
| | | operations. The I/O pins float to High-z when the chip is |
| | | deselected or when outputs are disabled. |
| R/Bn | Output | Ready/Busy indicates device operation status. R/Bn is an |
| | | open-drain output and does not float to High-z when the |
| | | chip is deselected or when outputs are disabled. When |
| | | low, it indicates that a program, erase, or random read |
| | | operation is in process; it goes high upon completion. |

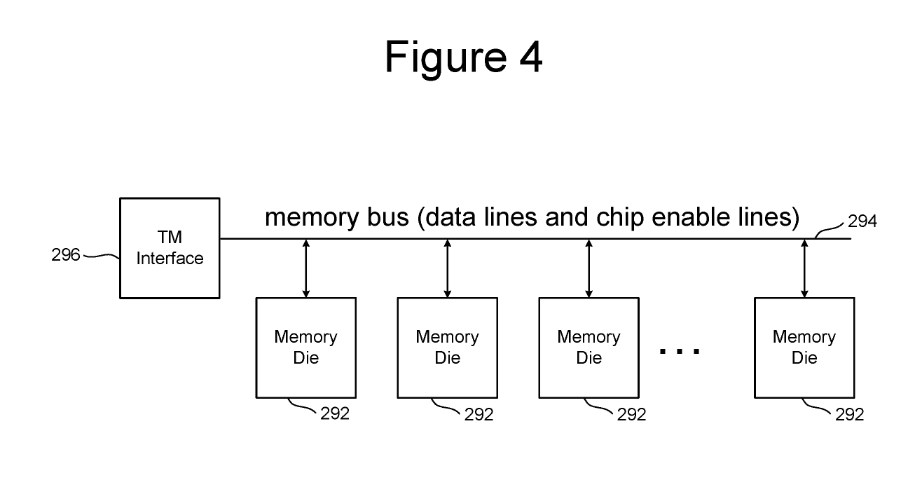

FIG. 4 is a block diagram of one embodiment of a memory package 104 that includes a plurality of memory die 292 connected to a memory bus (data lines and chip enable lines) 294. The memory bus 294 connects to a Toggle Mode Interface 296 for communicating with the TM Interface of an BEP circuit 112 (see e.g. FIG. 3). In some embodiments, the memory package can include a small controller connected to the memory bus and the TM Interface. The memory package can have one or more memory die. In one embodiment, each memory package includes eight or 16 memory die; however, other numbers of memory die can also be implemented. The technology described herein is not limited to any particular number of memory die.

In one embodiment, all of the memory die on a common memory package are connected to a common channel and while one of the memory die connected to the channel is writing data the controller is not free to perform operations with other memory die connected to the same channel. However, by decoupling the write transfer from the write operation, as explained below, the controller can be freed to perform operations with other memory die connected to the same channel between the decoupled write transfer and write operation.

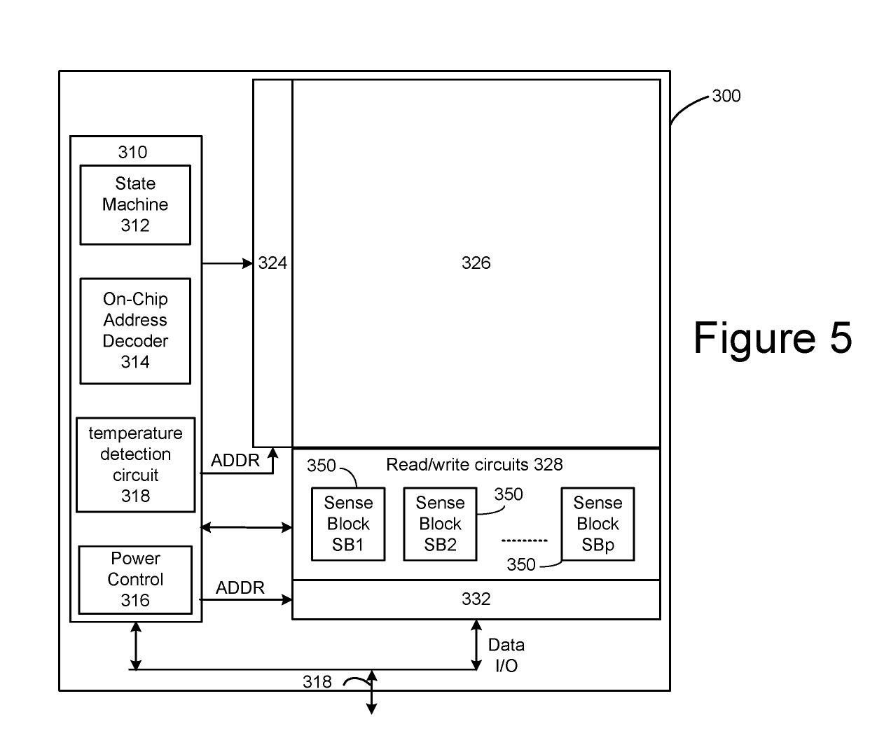

FIG. 5 is a functional block diagram of one embodiment of a memory die 300. The components depicted in FIG. 5 are electrical circuits. In one embodiment, each memory die 300 includes a memory structure 326, control circuitry 310, and read/write circuits 328. Memory structure 126 is addressable by word lines via a row decoder 324 and by bit lines via a column decoder 332. The read/write circuits 328 include multiple sense blocks 350 including SB1, SB2, . . . , SBp (sensing circuitry) and allow a page (or multiple pages) of data in multiple memory cells to be read or programmed in parallel. In one embodiment, each sense block include a sense amplifier and a set of latches connected to the bit line. The latches store data to be written and/or data that has been read.=Commands and data are transferred between the controller and the memory die 300 via lines 318. In one embodiment, memory die 108 includes a set of input and/or output (I/O) pins that connect to lines 118.

Control circuitry 310 cooperates with the read/write circuits 328 to perform memory operations (e.g., write, read, and others) on memory structure 326, and includes a state machine 312, an on-chip address decoder 314, a power control circuit 316 and a temperature detection circuit 318. State machine 312 provides die-level control of memory operations. In one embodiment, state machine 312 is programmable by software. In other embodiments, state machine 312 does not use software and is completely implemented in hardware (e.g., electrical circuits). In one embodiment, control circuitry 310 includes buffers such as registers, ROM fuses and other storage devices for storing default values such as base voltages and other parameters.

The on-chip address decoder 314 provides an address interface between addresses used by controller 102 to the hardware address used by the decoders 324 and 332. Power control module 316 controls the power and voltages supplied to the word lines and bit lines during memory operations. Power control module 316 may include charge pumps for creating voltages.

The sense blocks include bit line drivers. For purposes of this document, control circuitry 310, read/write circuits 328, and decoders 324/332 comprise a control circuit for memory structure 326. In other embodiments, other circuits that support and operate on memory structure 326 can be referred to as a control circuit.

In one embodiment, memory structure 326 comprises a three dimensional memory array of non-volatile memory cells in which multiple memory levels are formed above a single substrate, such as a wafer. The memory structure may comprise any type of non-volatile memory that are monolithically formed in one or more physical levels of arrays of memory cells having an active area disposed above a silicon (or other type of) substrate. In one example, the non-volatile memory cells comprise vertical NAND strings with charge-trapping material such as described, for example, in U.S. Pat. No. 9,721,662, incorporated herein by reference in its entirety.

In another embodiment, memory structure 326 comprises a two dimensional memory array of non-volatile memory cells. In one example, the non-volatile memory cells are NAND flash memory cells utilizing floating gates such as described, for example, in U.S. Pat. No. 9,082,502, incorporated herein by reference in its entirety. Other types of memory cells (e.g., NOR-type flash memory) can also be used.

The exact type of memory array architecture or memory cell included in memory structure 326 is not limited to the examples above. Many different types of memory array architectures or memory technologies can be used to form memory structure 326. No particular non-volatile memory technology is required for purposes of the new claimed embodiments proposed herein. Other examples of suitable technologies for memory cells of the memory structure 126 include ReRAM memories, magnetoresistive memory (e.g., MRAM, Spin Transfer Torque MRAM, Spin Orbit Torque MRAM), phase change memory (e.g., PCM), and the like. Examples of suitable technologies for memory cell architectures of the memory structure 126 include two dimensional arrays, three dimensional arrays, cross-point arrays, stacked two dimensional arrays, vertical bit line arrays, and the like.

One example of a ReRAM, or PCMRAM, cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

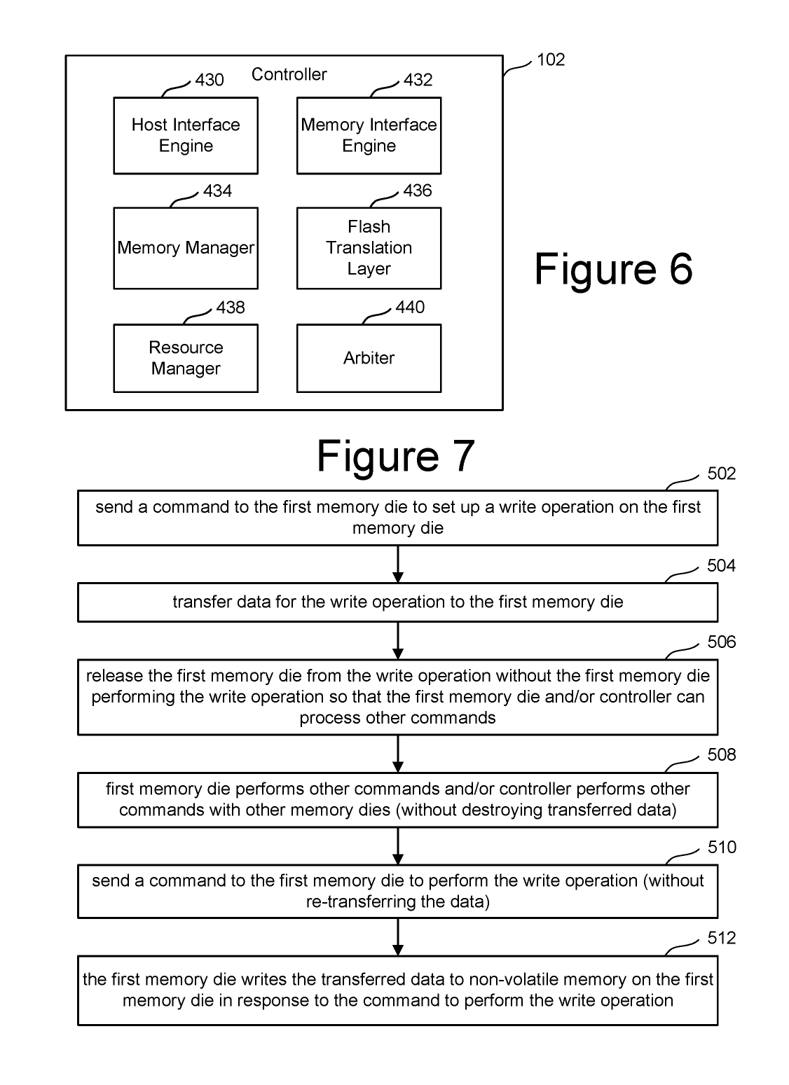

FIG. 6 is a logical block diagram depicting six software components of controller 102, including Host Interface Engine 430, Memory Interface Engine 432, Memory Manager 434, Flash Translation Layer 436, Resource Manager 438 and Arbiter 440. Host Interface Engine 430 is used to implement the interface between controller 102 and host 120. For example, Host Interface Engine 430 can be running on Host Processor 152 (see FIG. 2). Memory Interface Engine 432 is used to manage the interface between controller 102 and the various memory packages 104. For example, Memory Interface Engine 432 may be implemented on processors 220 and 250 (see FIG. 3). Memory Manager 434 is used to perform the various memory operations, including implementing reading and writing. In some embodiments, Memory Manager 434 implements a process to write data to a memory die in response to Arbiter 440. Flash Translation Layer 436 is used to translate between logical addresses used by host 120 and physical addresses used by the various memory die within memory system 100. Resource Manager 438 tracks the usage of resources available to the memory system 100, including usage and availability of power, heat and other resources. As discussed above, some systems may put a limit on how hot a memory system can get and how much power a memory system is using at a given moment in time. Resource Manager 438 will keep track of how hot a memory system is and how much power the memory system is using at the current moment time, as well as how much more power is available for the memory system to use and how much more heat can be dissipated.

Arbiter 440 arbitrates among tasks to perform. For example, host 120 may send multiple tasks for memory system to perform and Arbiter 440 will determine when those tasks are to be performed and instruct Memory Manager 434 when to perform the tasks. Memory Manager 434 will use Memory Interface Engine 432 and Flash Translation Layer 436 to perform the tasks. Arbiter 440 is in communication with the Resource Manager 438 to request resources, such as requesting whether there is sufficient resources (power, heat or other) available to perform a command and to reserve those resources for the command. For example, in response to availability of resources for a transfer as indicated by Resource Manager 438, Arbiter 440 selects a memory die to transfer data and transfers the data to the memory die followed by releasing the memory die to perform other commands without writing the data to non-volatile memory on the memory die. In response to availability of resources for a write operation as indicated by Resource Manager 438, Arbiter 440 selects the memory die and commands the memory die to write the data to non-volatile memory on the memory die without re-transferring the data.

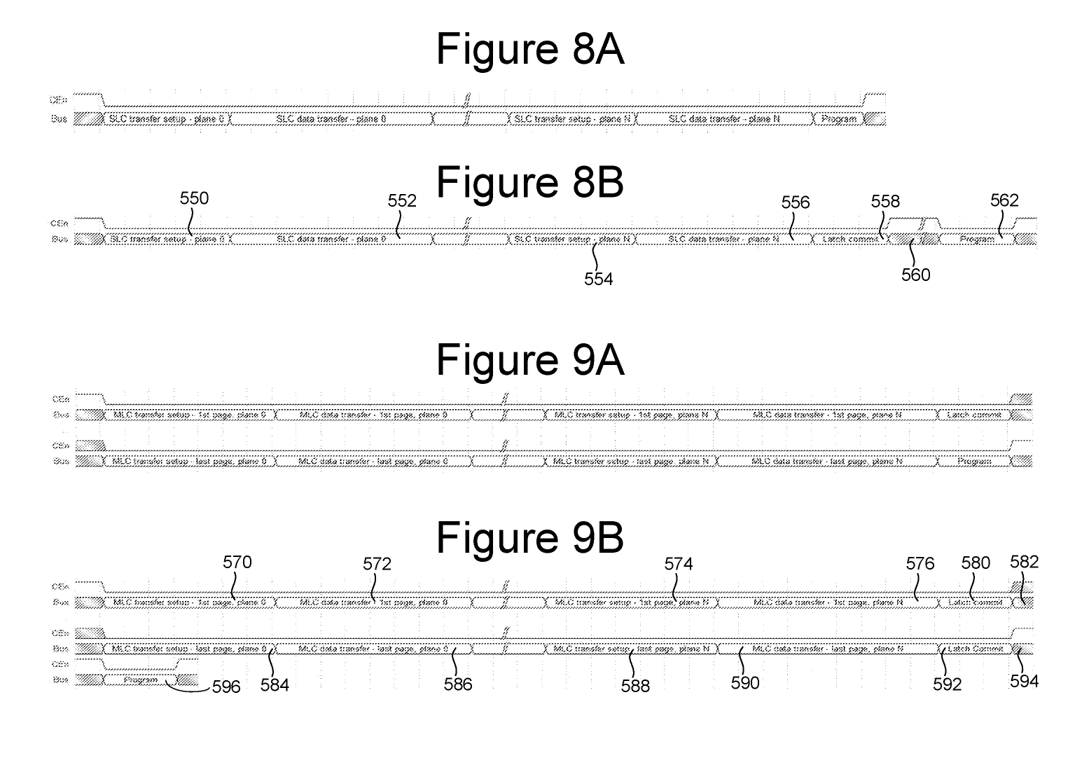

FIG. 7 is a flowchart describing one embodiment of a process for implementing the process of writing to non-volatile memory in a manner that decouples the write transfer and the write operation. The process of FIG. 7 is performed in response to controller 102 receiving host data (ie data from the host) and a request to write the received host data to the non-volatile memory 104. In one embodiment, steps 502-510 of FIG. 7 are performed by controller 102. In one example implementation, those steps are performed at the direction of Arbiter 440. In step 502 of FIG. 7, controller 102 sends a command to a memory die to set up a write operation on the memory die. As discussed above, in one embodiment memory system 100 includes multiple memory dies, and one of those memory dies is selected for receiving the command in step 502. For purposes of clarity only, the example discussed below will refer to the memory die selected for the write command in step 502 to be known as the first memory die. However, “first memory die” is only a label and does not indicate an order or sequence. In step 504 of FIG. 7, controller 102 transfers data for the write operation to the first memory die. Steps 502 and 504 include sending commands and transferring data for the write operation to the first memory die by transferring the command and data from the controller to the first memory die via A Toggle Mode Interface, and storing the data in latches (e.g., the latches in sense blocks 350 of FIG. 5) on the memory die. In other embodiments, storage devices other than latches can be used (e.g., flip flops).

In step 506, controller 102 releases the first memory die from the write operation without the first memory die performing the write operation so that the first memory die and/or the controller can process other commands. In one embodiment, the releasing of the first memory die includes committing the transferred data from step 504 into the latches of the memory die. The memory die then enters an idle state so that the memory die can perform other commands from controller 102. In one embodiment, as discussed above with respect to FIG. 5, memory die 300 includes state machine 312. Releasing first memory die in step 506 includes committing the transferred data to the latches in memory die 300 and enabling the state machine 312 to process new/other commands from controller 102 (or another entity). The state machine also enables controller 102 to interface with other memory dies after the command for releasing the first memory die is received. As part of the releasing of the first memory die and putting the first memory die in an idle state, the data committed to the latches (transferred to step 504) is protected from being destroyed or otherwise damaged.

In step 508, the first memory die performs other commands received from controller 102 or another entity. Alternatively, or in addition, controller 102 performs other commands with other memory die, all without destroying the data transferred in step 504. Since the first memory die was released from the write operation commanded in step 502, the first memory die is free to perform other commands and the controller is free to perform other commands. Thus, the transferring of data in step 504 is now decoupled from the actual writing of the data into non-volatile memory (which has not happened yet, but will happen in step 512).

In some embodiments, memory structure 326 and memory die 300 will include multiple planes. Therefore, data will be transferred in step 504 for multiple planes. For example, steps 502 and 504 can be performed multiple times, once for each plane.

In some embodiments, the memory system will include one bit per memory cell, which is referred to as single level cells (SLC). In other embodiments, the memory system will store multiple bits per memory cell, referred to as multiple level cells (MLC). For example, a system that stores multiple bits per memory cell may store three bits per memory cell. In that case, memory cells connected to a common word line may store three pages of data such that each of the three bits in every memory cell is in a different page of data. If there are three pages of data to be programmed, then, in one embodiment, steps 502 and 504 are performed three times, once for each page of data. Other embodiments may transfer the data in a different manner and may have more or less than three pages of data.

In step 510, controller 102 sends a command to the first memory die to perform the write operation. Note that controller 102 does not re-transfer the data to the first memory die. Thus, the data is only transferred once, in step 504, and not retransferred again. In step 512, the first memory die writes the transferred data to non-volatile memory on the first memory die in response to the command to perform the write operation (step 510). As per the above discussion, the transferred data in step 504 is decoupled from the actual writing of data in step 512 since the memory die and controller were released in step 506 to perform other commands in the interim. In this manner, if there is resource budget (power, heat or other resource) to perform the transfer but there is not resource budget to perform the write operation, then steps 502-508 can be performed without delay. As soon as their resources are available for performing the write operation, then steps 510 and 512 can be performed without wasting time transferring data.

Note that in step 508, one example of the controller performing other commands with other memory dies includes the controller sending an additional command to a second memory die after releasing the first memory die and prior to sending the command to the first memory die to perform the write operation. Performance of the additional command does not destroy the transferred data on the first memory die that has not yet been written to non-volatile memory on the first memory die. The second memory die performs the additional command prior to the controller sending the command to the first memory die to perform the write operation.

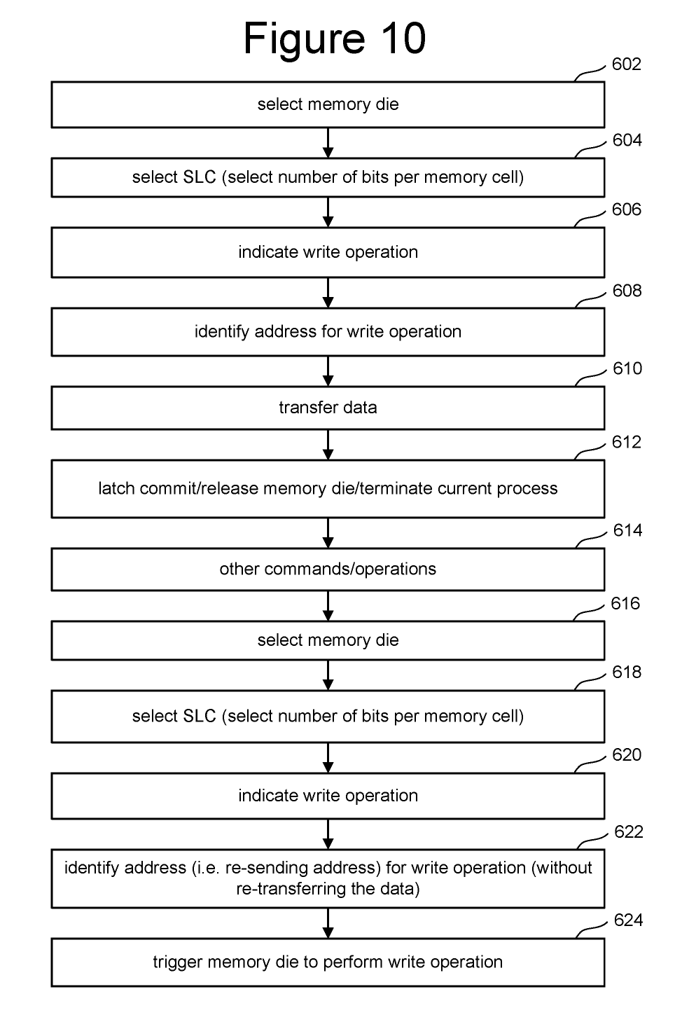

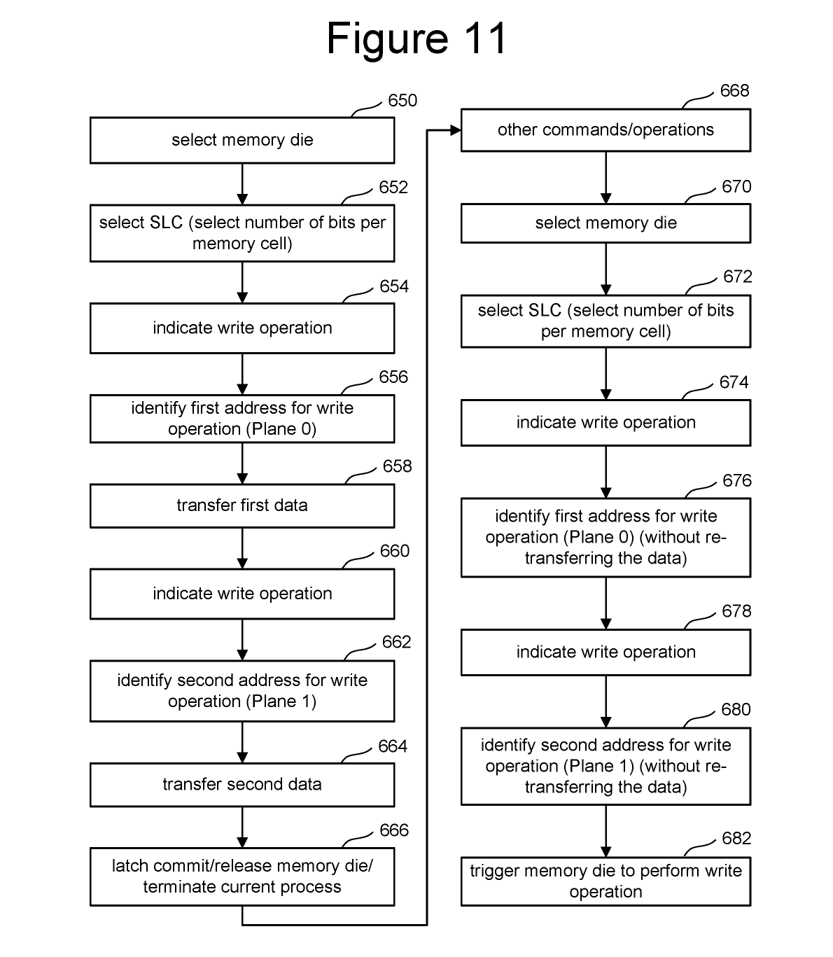

FIGS. 8A, 8B, 9A and 9B are signal diagrams depicting the behavior of the chip enable signal CEn (See Table 1, above) and bus signals Bus (see Bus [0:7] in Table 1) for the memory die 300 (e.g., the first memory die recited in the process of FIG. 7). FIG. 8A shows the signal diagram when the transfer of data and the writing of data are not decoupled, and memory structure 326 of memory die 300 includes multiple planes (N planes). FIG. 8B depicts the example where the process of FIG. 7 is performed such that the transfer of data and the writing of data are decoupled and memory structure 326 includes multiple planes (N planes).

As depicted in FIG. 8A, there was an SLC transfer setup for plane 0 filed by SLC data transfer for plane 0 on the Bus. The SLC transfer setup and SLC data transfer are repeated for each of the planes until plane N. Immediately following the SLC transfer setup for plane N and the SLC data transfer for plane N, the memory system writes the transferred data (Program) to planes 0-N.

FIG. 8B applies to an embodiment that decouples the write transfer and the write operation as per FIG. 7. FIG. 8B shows the SLC transfer setup for Plane 0 (550) followed by SLC data transfer for Plane 0 (552) on the Bus. The SLC transfer setup and SLC data transfer are repeated for each of the planes until the SLC transfer setup for plane N (554) and the SLC data transfer for plane N (556). Note that the transfer setups 550/554 are analogous to step 502 of FIG. 7 and the SLC data transfers 552/556 are analogous to step 504 of FIG. 7. After the SLC data transfer from Plane N (556), instead of immediately writing the data (as depicted in FIG. 8A), the controller issues a latch commit command 558, which is analogous to step 506 of FIG. 7 (i.e. releasing the first memory die). After the latch commit command 558, there is a period of time 560 where other commands are performed by the first memory die and/or controller, which is analogous to step 508 of FIG. 7. After some period of time (e.g., when there are sufficient resources to perform the write operation), the memory system writes the already transferred data (Program 562), which is analogous to steps 510 and 512 of FIG. 7. The Chip Enable signal CEn is low during the transfer setups and data transfers because the memory die needs to be selected to process the commands. The Chip Enable signal CEn is raised high after the latch commit 580 to indicate that the memory die is no longer selected; therefore, other memory dies can be selected for performing an operation. The Chip Enable sign CEn n is active again (low) in order to perform the write operation (Program 562).

FIGS. 9A and 9B are signal diagrams depicting the behavior of the signals CEn and Bus for a memory die 108 that stores multiple bits per memory cell (MLC data). FIG. 9A depicts an example when the write transfer and write operation are not decoupled. FIG. 9A shows data being transferred for the first page of each of the planes as the Bus carries the commands “MLC transfer setup—1^{st} page, plane 0”, “MLC data transfer—1^{st} page, plane 0”, . . . “MLC transfer setup—1^{st} page, plane N”, “MLC data transfer—1^{st} page, plane N”. A “Latch commit” command is then transmitted on the bus. Data is then transferred for the last page of each of the planes as the Bus carries the commands of “MLC transfer setup—last page, plane 0”, “MLC data transfer—last page, plane 0”, . . . “MLC transfer setup—last page, plane N”, “MLC data transfer—last page, plane N.” If there are more than two pages (e.g., more than two bits per memory cell), then additional pages of data will be transferred for each plane. Immediately after transferring the data for the last page, a write command (program) is transmitted on the Bus to the selected memory die.

On the other hand, FIG. 9B applies to a system that decouples the write transfer and the write operation. FIG. 9B shows data transfer for the first page of each plane followed by data transfer for the last page of each plane. If there are additional pages, they would be transferred after the first page and before the last page. For example, FIG. 9B shows “MLC transfer setup—1^{st} page, plane 0” (570) followed by “MLC data transfer—1^{st} page, plane 0” (572) on the Bus. The transfer setup and data transfer is repeated for each plane until “MLC data transfer setup—1st page, plane N” (574) and “MLC data transfer—1^{st} page, plane N” (576) are transmitted on the Bus. After completing the transfer of the first page for each plane, a latch commit 580 is transmitted on the Bus. FIG. 9B also shows the Bus transmitting “MLC transfer setup—last page, plane 0” (584) followed by the “MLC data transfer—last page, plane 0” (586). The transfer setup for the last page and the data transfer for the last page are repeated for each plane concluding with the “MLC data transfer setup —last page, plane N” (588) and “MLC data transfer—last page, plane N” (590). Note that each of the transfer setups 570, 574, 584 and 588 are analogous to step 502. Each of the MLC data transfers 572, 576, 586 and 590 are analogous to step 504 of FIG. 7. Subsequent to the MLC data transfer for the last page of plane N (590), the controller issues a latch commit 592 to the first memory die, which is an example of step 506 of FIG. 7. In the period 594 subsequent to the latch commit, the first memory die can perform other commands and/or the controller can perform other commands with other memory dies (as per step 508 of FIG. 7). At a later time when resources are available to perform the write operation, controller 102 issues a write command (Program 596) to the first memory die, which is analogous to steps 510 and 512 of FIG. 7. When the transfer setups and data transfers are being performed, the chip enable signal CEn is low, thereby selecting the memory die. After the latch commit 580 and 592, the chip enable signal goes high; thereby unselecting the memory die so that other memory dies can be selected to perform commands. When controller 102 issue a write command (Program 596) to the memory die, the chip enable signal CEn is low to select the memory die.

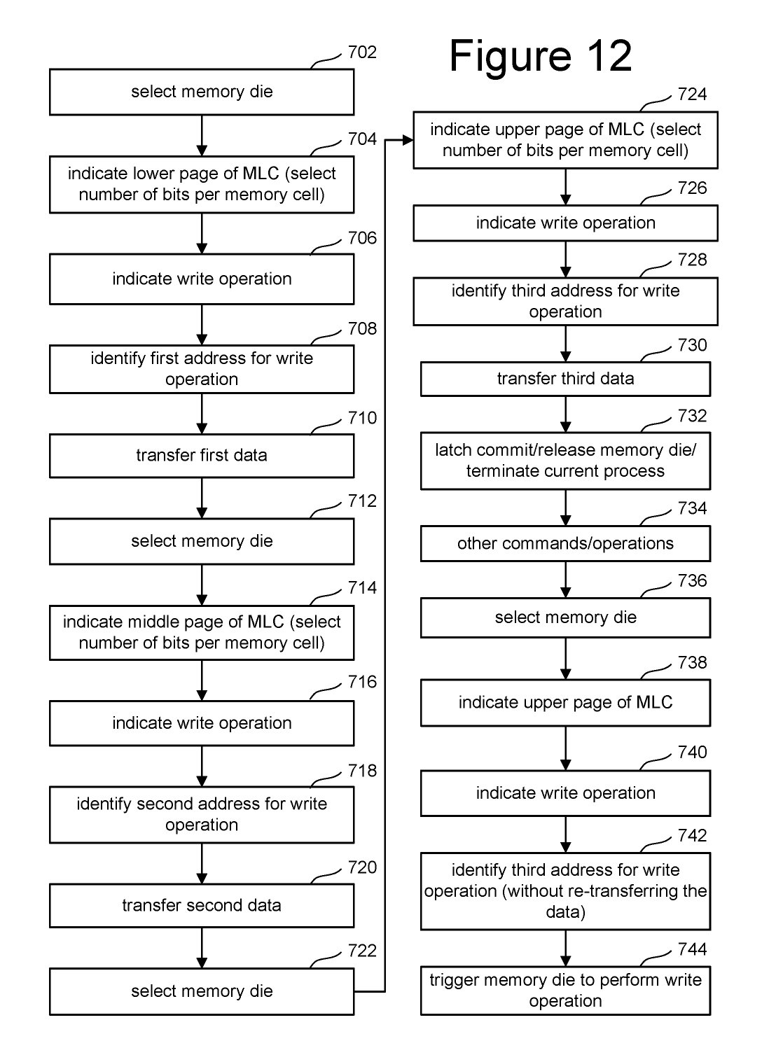

FIG. 10 is a flowchart describing one embodiment of a process implementing a write to memory that decouples the write transfer and the write operation for a memory system that stores one bit per memory cell but and has one plane in memory structure 326. That is the process of FIG. 10 depicts more implementation details of one embodiment of the process of FIG. 7. In one embodiment, the process of FIG. 10 is performed by controller 102 (e.g., at the direction of Arbiter 440). In one embodiment, the process of FIG. 10 is performed in response to receiving a write request from host 120 that is requesting that the memory system store host data. FIG. 10 is for an embodiment that stores one bit per memory cell and only has one plane in memory structure 326. In one embodiment, each of the steps of FIG. 10 include controller 102 sending a command or data to the selected memory die via the Toggle Mode Interface discussed above

In step 602 of FIG. 10, controller 102 selects a memory die to perform the write operation. In step 604, controller 102 selects the number of bits to be stored per memory cell. In the example of FIG. 10, controller 102 is selecting SLC (one bit per memory cell). In step 606, controller 102 indicates that a write operation should be performed. In step 608, controller 102 identifies an address for the write operation. Steps 602-608 provide an example of step 502 of FIG. 7. In step 610, controller 102 transfers the data for the write operation from controller 102 to the selected memory die. Step 610 is the example of step 504 of FIG. 7. In step 612, controller 102 transmits a latch commit command to the memory die, thereby releasing the memory die from the current write process. Step 612 is an example of step 506 of FIG. 7. In step 614, controller performs other commands and/or other operations with other memory die. Alternatively, or in addition, the selected memory die (selected in step 602) can perform other operations (other than the write operation indicated in step 606). By releasing the memory die in step 612, the transfer of data in step 610 is decoupled from the write operation which has not occurred yet.

When controller 102 is ready to perform the write operation, controller 102 selects the memory die (again) (step 616). In step 618, controller 102 selects SLC. In step 620, controller 102 indicates that a write operation is to be performed. In step 622, controller 102 identifies the address for the write operation (again). That is, controller 102 is resending the address for the write operation to the selected memory die. However, controller 102 will not re-transfer the data to the memory die for the write operation. This is because the data was already transferred in step 610 and it was committed to the latches in step 612. In step 624, controller 102 triggers the memory die to perform the write operation. Steps 616-624 are an example implementation of step 510 of FIG. 7. In response to the trigger of step 624, the selected memory die will write the transferred data to non-volatile memory on the memory die.

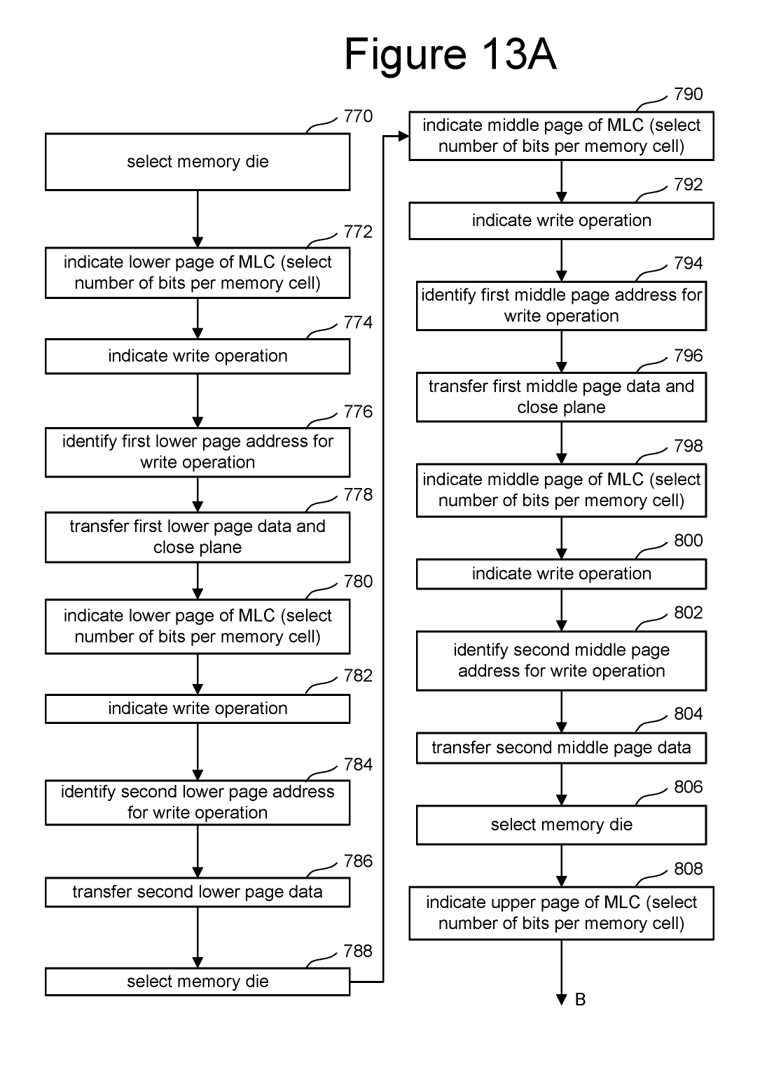

FIG. 11 is a flowchart describing more details of an example implementation of the process of FIG. 7 for a memory system that stores one bit per memory cell and has multiple planes in memory structure 326. In one embodiment, the process of FIG. 11 is performed by controller 102 (e.g., at the control of Arbiter 440). Each of the steps of FIG. 11 includes controller 102 sending a command to a memory die via the Toggle Mode Interface discussed above. In step 650 of FIG. 11, controller 102 selects a memory die for the write operation. In one embodiment, the process of FIG. 11 is performed in response to receiving a request to write data from host 120. In step 652, controller 102 selects a number of bits per memory cell; for example, controller 102 selects SLC. In step 654, controller 102 indicates that a write operation is to be performed (e.g., send a write command). In step 656, controller 102 identifies a first address for the write operation. This first address identifies a location in Plane 0. Steps 650-656 are an example implementation of step 502 of FIG. 7. In step 658 of FIG. 11, first data is transferred from controller 102 to the memory die. Step 658 is an example of step 504 of FIG. 7. In step 660 of FIG. 11, controller 102 indicate a write operation is to be performed by the memory die. This is a second write command. In step 662, controller 102 identify a second address for the second write operation. The second address identifies a location plane 1. Steps 660 and 662 are another example implementation of step 502 of FIG. 7. In step 664, controller 102 transfers second data from controller 102 to the selected memory die. The second data is for the write operation indicated in step 660. Step 664 is another example implementation of step 504 of FIG. 7. In step 666, controller 102 issues a latch commit, which releases the memory die and terminates the current memory write process. Step 666 is an example implementation of step 506. In step 668, controller 102 performs other commands with other memory die and/or the selected memory die (step 650) performs other commands/operations. Step 668 is an example implementation of step 508 of FIG. 7.

When controller 102 determines that there is sufficient resources or it is appropriate to perform the write operation associated with the transfer of write data that occurred based on steps 650-666, controller 102 performs step 670, which includes selecting the memory die for the write operation. This would be the same memory die selected in step 650. In step 672, controller 102 selects SLC. In step 674, controller 102 indicates that a write operation is to be performed. Thus, steps 670-674 are somewhat repetitive of steps 650-654. In step 676 of FIG. 11, controller 102 identifies the first write address (again) for the write operation without retransferring the first data. This first write address identifies the location in plane 0. In step 678, controller 102 indicates (again) that as write operation is to be performed. In step 680, controller 102 identifies the second address (again) for the write operation, which identifies a location in plane 1. Step 680 is performed without retransferring the data. In step 682, controller 102 triggers the memory die to perform the write operation. Steps 670-682 are an example implementation of step 510 of FIG. 7. In response to step 682, the selected memory die (see steps 650 and 670, both of which selected the same memory die) will write the transferred data to both planes for the non-volatile memory structure 326.

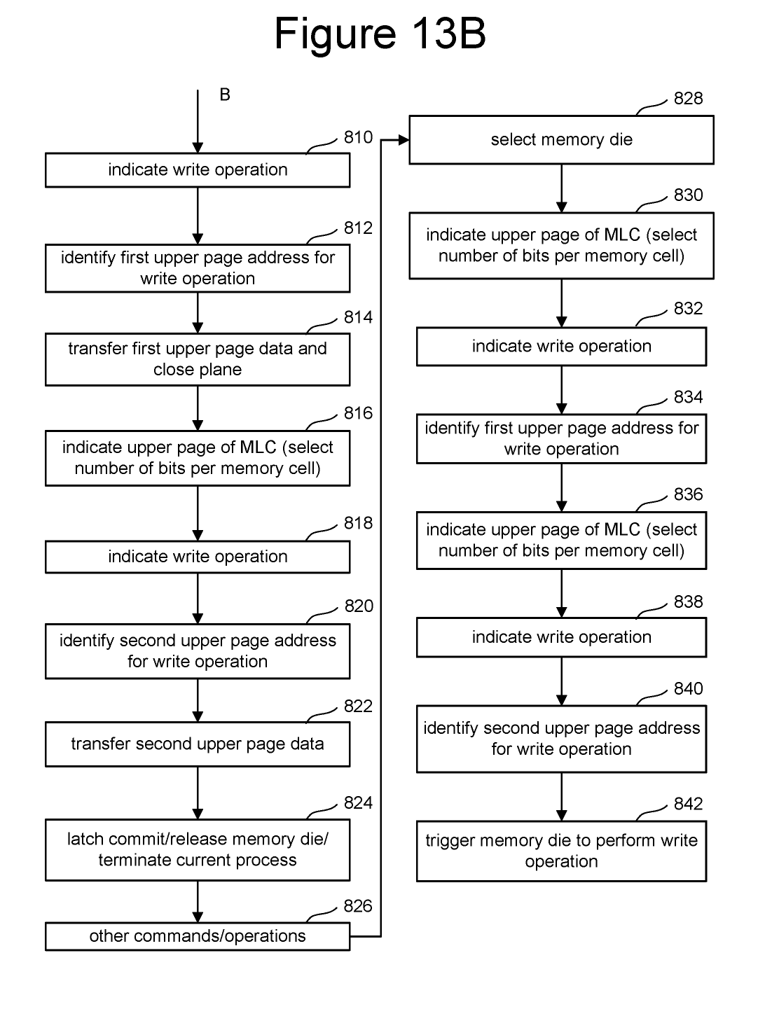

FIG. 12 is a flowchart describing more details of an example implementation of the process of FIG. 7 for a memory system that stores multiple bits per memory cell in one plane. In the embodiment of FIG. 12, the memory system stores three bits per memory cell; however, in other embodiments more or less than three bits can be stored per memory cell. In one embodiment, the process of FIG. 12 is performed by controller 102 (e.g., at the direction of Arbiter 440), such that each step of FIG. 12 includes controller 102 sending a command to the selected memory die via the Toggle Mode Interface discussed above.

In step 702 of FIG. 12, controller 102 selects a memory die for performing the write operation. In one embodiment, the process of FIG. 12 is performed in response to receiving a request to write data from host 120. In step 704, controller 102 indicates that the next command will be for the lower page for an MLC embodiment. That is, controller 102 is selecting that there will be multiple bits per memory cell, and the next command is for the lower page. In one embodiment, the three pages of data will include a lower page, a middle page and an upper page. Each memory cell will store one bit in the lower page, one bit in the middle page, and one bit in the upper page. In step 706, controller 102 indicates a write operation. In step 708, controller 102 identifies the first address for the write operation. Steps 702-708 are an example implementation of step 502 of FIG. 7. In step 710, controller 102 transfers first data for the write operation indicated in step 706. Step 710 is an example implementation of step 504 of FIG. 7. In step 712, controller 102 selects the memory die. In one embodiment, the same memory die is selected as in step 702. In step 714, controller 102 indicates that this command sequence is for the middle page of MLC data. In step 716, the controller 102 indicates a write operation to be performed. In step 718, controller 102 identifies the second address for the write operation. The second address is for the middle page of data. Steps 712-718 are an example implementation of step 502 of FIG. 7. In step 720, the second data is transferred from controller 102 to the memory die selected in step 712. Step 720 is an example implementation of step 504. The second data transferred in step 720 is the middle page of data associated with the second address.

In step 722, controller 102 selects the memory die. In one embodiment, the same memory die is selected as in steps 702 and 712. In step 724, controller 102 indicates that it is now sending commands for the upper page of the MLC data. In step 726, a write indication is indicated. In step 728, controller 102 identifies the third address for the write operation. Steps 722-728 are an example implementation of step 502. In step 730, third data is transferred from controller 102 to the selected memory die. Step 730 is an example implementation of step 504. The third data transferred in step 730 is the data for the upper page. In step 732, controller 102 issues a latch commit, thereby releasing the selected memory die from the write operation. This will terminate the current write process. Step 732 is an example implementation of step 506. In step 734, controller 102 can perform other commands or operations with other memory die. Alternatively, or in addition, the selected memory die can perform other operations/commands. Step 734 is an example implementation of step 508 of FIG. 7.

When controller 102 deems inappropriate to perform the write operation of the decoupled write transfer and write operation, controller 102 select the memory die for the write operation in step 736. In one embodiment, the same memory die will be selected in step 736 as was selected in steps 702, 712 and 722. In step 738, controller 102 indicates that the commands currently being sent are for the upper page of the MLC data. In step 740, write operation is indicated. In step 742, controller 102 identifies the third address (again), which is the address for the upper page for the write operation. The data previously transferred will not be re-transferred. In step 744, controller 102 triggers the memory die to perform the write operation. Steps 736-744 are an example implementation of step 510. In response to step 744, the selected memory die will write the transferred data for the lower page, middle page and upper page to the non-volatile memory structure 326.

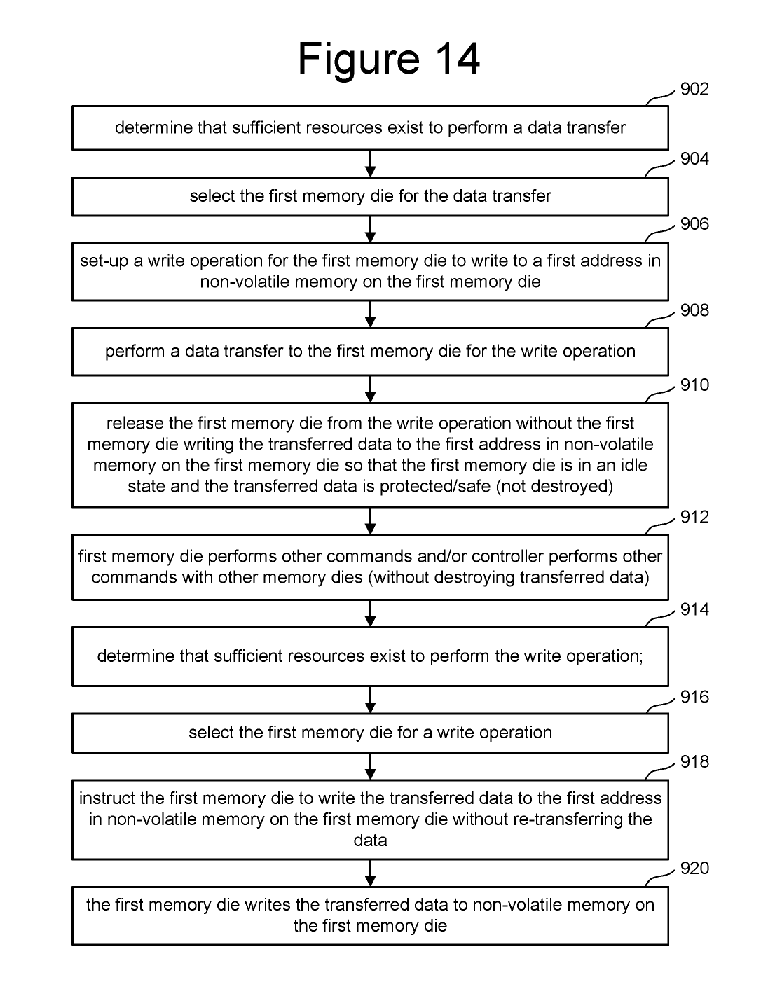

FIGS. 13A and 13B depict a flowchart that describes details of an implementation of the process of FIG. 7 for a memory system that stores multiple bits per memory cell in multiple planes of memory structure 326. In the example of FIGS. 13A-13B, the memory system stores three bits per memory cell with each bit being in a different logical page being referred to as the lower page, middle page and upper page. Additionally, the example of FIG. 13B includes a memory structure 326 that has two planes of memory cells. In one embodiment, the process depicted in FIGS. 13A and 13B is performed by controller 102 (e.g., at the direction of Arbiter 440). In one embodiment, the process of FIGS. 13A and 13B is performed in response to a request to write host data from host 120. Each step of FIGS. 13A and 13B include controller 102 sending a command to the selected memory die via the Toggle Mode Interface discussed above.

In step 770 of FIG. 13A, controller 102 selects a memory die. In step 772, controller 102 indicates that lower page of MLC data is being transmitted. In step 774, a write operation is indicated. In step 776, controller 102 identifies a first lower page address for the write operation. In one embodiment, steps 770-776 provide an example implementation of step 502 of FIG. 7. In step 778 of FIG. 13A, controller 102 transfers the first lower page data from controller 102 to the memory die and closes the plane. Step 778 is an example implementation of step 504 of FIG. 7. In step 780, controller 102 indicates that the data being transferred is for the lower page of MLC data. In step 782, controller 102 indicates a write operation to be performed. In step 784, controller 102 identifies a second lower page address for the write operation. The first lower page address in step 776 is for the first plane and the second lower page address for step 784 is for the second plane. Steps 780-784 are an example implementation of step 502 of FIG. 7. In step 786, controller 102 transfers second lower page data. Step 786 is an example implementation of step 504.

In step 788, controller 102 selects a memory die. In one embodiment, the memory die selected in step 788 is the same memory die selected in step 770. In step 790, controller 102 indicates that the next data being transferred is for the middle page of MLC data. In step 792, controller 102 indicates a write operation to be performed. In step 794, controller 102 identifies a first middle page address for the write operation. Steps 788-794 are an example implementation of step 502 of FIG. 7. In step 796 of FIG. 13A, controller 102 transfers first middle page data from controller 102 to the selected memory die enclosed as the plane. Step 796 is an example implementation of step 504. In step 798, controller 102 indicates that a middle page of data will be a transferred. In step 800, controller 102 indicates a write operation is to be performed. In step 802, controller 102 identifies a second middle page address for the write operation. Steps 798-802 are example implementations of step 502 of FIG. 7. In step 804, controller 102 transfers the second middle page of data. Step 804 is an example implementation of step 504 of FIG. 7.

In step 806, controller 102 selects memory die. In one embodiment, the same memory die is selected in step 806 as previously selected in steps 788 and 770. In step 808, controller 102 indicates that the data to be transferred is upper page data of MLC data. In step 810 (see FIG. 13B), controller 102 indicates a write operation is to be performed. In step 812, controller 102 identifies a first upper page address for the write operation. Steps 806-812 are an example implementation of step 502 of FIG. 7. In step 814, a first upper page data is transferred from controller 102 to selected memory die, and the plane is closed. Step 814 is an example implementation of step 504 of FIG. 7. In step 816, controller 102 indicates that a data transfer will be performed using upper page MLC data. In step 818, controller 102 indicates a write operation is to be performed. In step 820, controller 102 identifies second upper page address for the write operation. Steps 816-820 are an example implementation of step 502 of FIG. 7. In step 822, second upper page data is transferred from controller 102 to the selected memory die. Step 822 is an example implementation of step 504. In step 824, controller 102 issues a latch commit to the memory die to release the memory die from the current write operation. This terminates the current process. Step 824 is an example implementation of step 506 of FIG. 7. In step 826, controller 102 performs other commands/operations with other memory die. Alternatively, or in addition, the selected memory die from steps 770, 788 and 806 is used to perform other commands/operations. However, the data previously transferred is not destroyed or damaged.

At a future time when controller 102 deems it appropriate to perform the write operation of the decoupled write transfer and write operation, then controller 102 will select the memory die in step 828. The same memory die selected in 828 as previously selected in steps 770, 788 and 806. In one embodiment, step 828 will be performed when controller 102 confirms that there are sufficient resources (heat, power and/or other types of resources) available to perform the write operation. In step 830, controller 102 indicates that upper page of MLC data is to be written. In step 832, controller 102 indicates a write operation to be performed. In step 834, controller 102 identifies the first upper page address for the write operation. The first upper page write address from step 834 is the same first upper page address as in step 814. In step 836, controller 102 indicates an upper page of data from MLC data to be transferred (again). In step 838, controller 102 indicates a write operation to be performed. In step 840, controller 102 identifies the second upper page address for the write operation. This is the same second upper page address as identified in step 820. In step 842, controller 102 triggers the memory die to perform the write operation. Steps 828-840 are an example implementation of step 510 of FIG. 7. In response to the trigger of step 842, the selected memory die will write all three pages of data to the first plane and all three pages of data to the second plane of non-volatile memory.

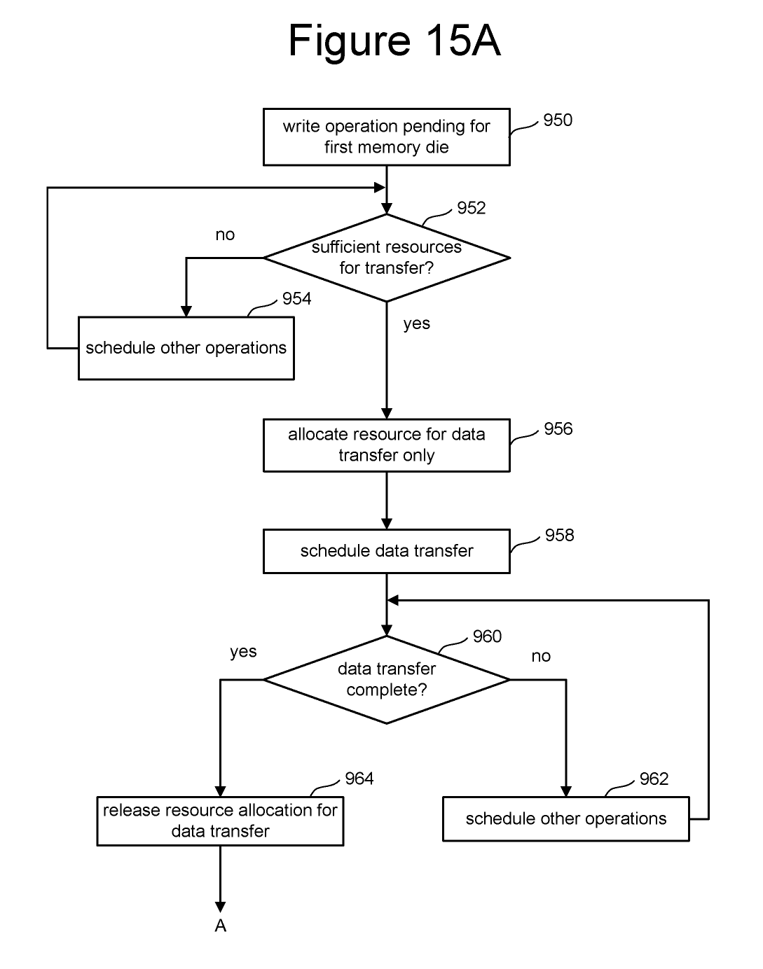

As discussed above, one reason for decoupling the write transfer and the write operation is to more efficiently manage resources. Examples of resources managed include power and heat; however, other resources can also be managed. FIG. 14 is a flowchart describing details of an example implementation of the process of FIG. 7 that decouples the write transfer and write operation for purposes of more efficiently managing resources. In step 902 of FIG. 14, controller 102 determines that sufficient resources exist to perform a data transfer. For example, Arbiter 440 may request resources from Resource Manager 438. Resource manager 438 will determine if sufficient resources exist to perform the data transfer. In response to determining if sufficient resources exist to perform the data transfer, controller 102 will perform steps 904 and 906, which collectively are one example implementation of step 502 of FIG. 7. In step 904 of FIG. 14, controller 102 selects the first memory die for the data transfer. In step 906, controller 102 sets up a write operation for the first memory die to write to a first address in non-volatile memory on the first memory die. In step 908, controller 102 performs a data transfer to transfer the data for the write operation from controller 102 to the first memory die. Step 908 is one example implementation of step 504 of FIG. 7. In step 910 of FIG. 14, controller 102 releases the first memory die from the write operation without the first memory die writing the transferred data to the first address in non-volatile memory on the first memory die so that the first memory die is in idle state and the transferred data is protected (e.g. safe so that it is not destroyed). Step 910 is an example implementation of step 506 of FIG. 7.

In step 912 of FIG. 14, first memory die performs other commands. Alternatively, the controller 102 performs other commands with other memory dies. In either circumstance, the transferred data (see step 908) is not destroyed by the other commands performed in step 912. In some embodiments step 912 is skipped. Step 912 is one example implementation to step 508.

In step 914, controller 102 determines that sufficient resources exist to perform the write operation. In one example embodiment, Arbiter 440 requests resources to be reserved for the write operation. This request is provided to Resource Manager 438 which determines whether the resources are available. If the resources are available for the write operation, Arbiter 440 will reserve those resources. In some embodiments, step 914 could be performed earlier in the process. In some situations, if step 914 is performed right after step 910 then step 912 can be skipped. In one example, Arbiter 440 requests X amount of power from Resource Manager 438. If Resource Manager 434 determines that X amount of power is available, then Arbiter 440 reserves X amount of power for the write operation and proceeds to perform the write operation. If X amount of power is not available, Arbiter 440 will schedule other tasks (rather than perform the write operation at this time) and wait to perform the write operation until Resource Manager 434 indicates that X amount of power is available.

In response to determining that sufficient resources exist to perform the write operation, controller 102 selects the first memory die for the write operation in step 916. In step 918, controller 102 instructs the first memory die to write the transferred data to the first address in the non-volatile memory of the first memory die without re-transferring the data. Steps 916 and 918 are example implementations of step 510 of FIG. 7. In step 920, the first memory die writes the transfer data to the non-volatile memory on the first memory die. Step 920 is an example implementation of step 512 of FIG. 7.

Note that the process of FIG. 14 can be used with the detailed implementations of FIGS. 10-13 such that step 902 of FIG. 14 is performed before any of the example implementations of step 502 and step 914 is performed before any the example implementations of step 510.

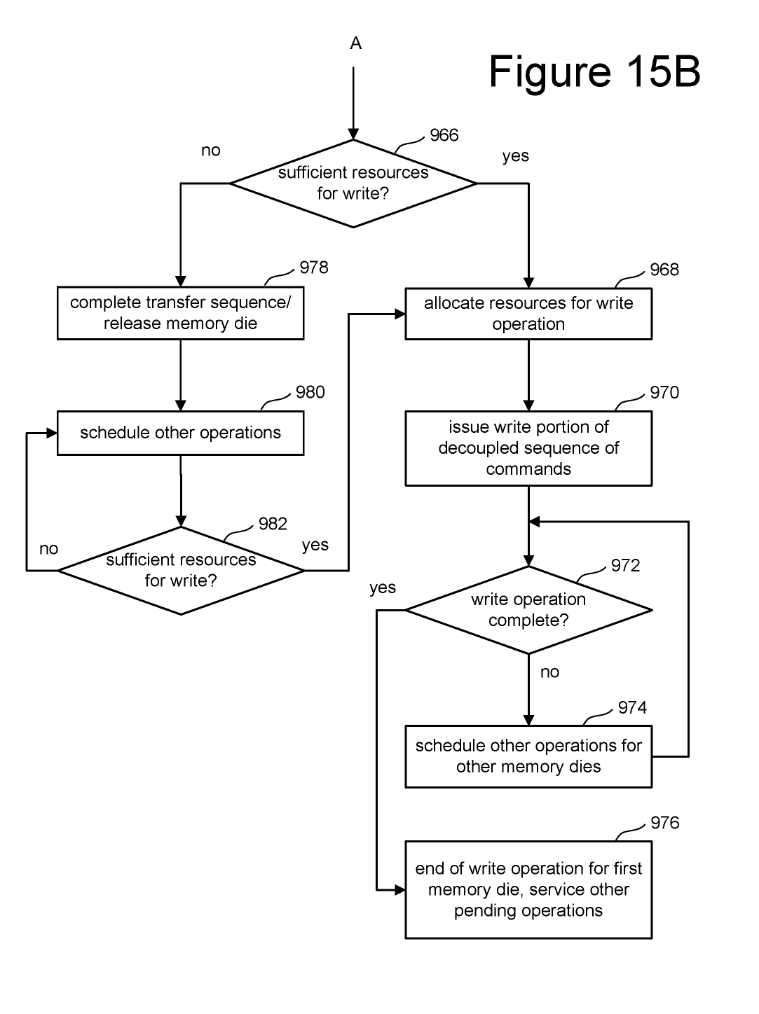

FIGS. 15A and 15B together depict a flowchart describing one embodiment of a process performed by Arbiter 440 in order to implement the process of FIG. 14, when performing any of the example processes of FIG. 7 or 10-13A/B. In the embodiment of FIGS. 15A and 15B, Arbiter 440 arbitrates among tasks to perform. Arbiter 440 is in communication with Resource Manager 438 to request resources from Resource Manager 438. In response to availability of resources for a transfer as indicated by Resource Manager 438, Arbiter 440 selects a memory die to transfer data and transfers the data to that selected memory die followed by release of the memory die to perform other commands (and/or releasing the controller to perform other commands) without writing the data to the non-volatile memory in the memory die. In response to availability of resources for a write command, as indicated by the Resource Manager 438, Arbiter 440 again selects the same memory die and commands that selected memory die to write data to non-volatile memory on the memory die without re-transferring the data.

In step 950 of FIG. 15A, there is a write operation pending for the first memory die. In step 952, Arbiter 440 communicates with Resource Manager 438 to determine whether there are sufficient resources available for a data transfer. The resources can be heat resources and/or power resources (or other types of resources). If there are not sufficient resource available for the transfer (step 952), then Arbiter 440 will schedule other operations (step 954) and the process will loop back to step 952. If there are sufficient resources available for a data transfer (e.g., sufficient heat resources available and sufficient power resources available to transfer data from the controller to the memory die), then in step 956 Arbiter 440 will allocate the resources for the data transfer only. In step 958, Arbiter 440 schedule the data transfer. In one embodiment, step 958 is associated with steps 502 and 504 of FIG. 7. In step 960, Arbiter 440 determines whether data transfer is complete. If the data transfer is not complete, then in step 962 Arbiter 440 schedules other operations to be performed while the data transfer is occurring. These other operations can be performed by other memory dies. After step 962, the process loops back to step 960. If the data transfer is complete (step 960), then in step 964, Arbiter 440 release the resources allocated for the data transfer. This way the resources can be used for a different command. As discussed above, there is only so much heat that can be dissipated at one time and so much power used at the same time. If the amount of power and heat is reserved for the data transfer, once the data transfer is completed, that power and heat can be used for another command.

After step 964 (see FIG. 15A), the process continues to step 966 (see FIG. 15B). In step 966, Arbiter 440 determines whether there are sufficient resources for the write operation. In one embodiment, step 966 includes Arbiter 440 communicating with Resource Manager 438 to determine whether there are sufficient resources for the write operation. In one embodiment it is Resource Manager 438 that will determine whether there are sufficient resources available and communicate that information to Arbiter 440. If there are sufficient resources available for the write operation, then the step 968 Arbiter 440 allocates the resources for the write operation. In step 970, Arbiter 440 issues a command to perform a write operation (of the decoupled sequence of write transfer and write operation) to the memory die. This is analogous to step 510 of FIG. 7. In step 972, Arbiter 440 determines whether the write operation is completed. If the write operation is not completed, then Arbiter 440 can schedule other operations to be performed on other memory dies. After step 974, the process will lead back to step 972. If the write operation has completed, then in step 976, Arbiter 440 concludes that the write operation has ended for that memory die and now Arbiter 440 can service other pending operations.

If in step 966 Resource Manager 438 informs Arbiter 440 that there is not sufficient resources available for a write operation, then in step 978 Arbiter complete the transfer sequence and releases the memory die so that the memory die and/or the controller can perform other commands/actions. Step 978 of FIG. 15B is analogous to step 506 of FIG. 7. In step 980, Arbiter 440 schedules other operations for the same memory die or other memory die. Step 980 of FIG. 15B is analogous to step 580 of FIG. 7. In step 982, Arbiter 440 determines whether there are sufficient resources for the write operation. In one embodiment, step 966 includes Arbiter 440 communicating with Resource Manager 438 to determine whether there are sufficient resources for the write operation. As mentioned above, in one embodiment it is Resource Manager 438 that will determine whether there are sufficient resources available and communicate that information to Arbiter 440. If there are sufficient resources available for the write operation, then the step 968 Arbiter 440 allocates the resources for the write operation; otherwise, the process loops back to step 980 and other operations are scheduled for the same memory die or a different memory die.

The above-described embodiments decouple the write transfer from the write operation, which enables more concurrent operations to be performed and results in improved performance of the memory system when constrained by power consumption or thermal limits (or other limitations on resources).

One embodiment includes an apparatus comprising a first memory die and a controller connected to the first memory die. The controller is configured to send a command to the first memory die to set up a write operation on the first memory die and transfer data for the write operation to the first memory die. The controller configured to release the first memory die from the write operation after transferring the data and without the first memory die performing the write operation so that the first memory die can process other commands. The controller is configured to send a command to the first memory die to perform the write operation subsequent to releasing the first memory die from the write operation. The first memory die is configured to write the transferred data to non-volatile memory on the first memory die in response to the command to perform the write operation.

One embodiment includes an apparatus comprising a host interface, a memory interface and a processor connected to the memory interface and the host interface. The processor is configured to select a first memory die of a plurality of memory dies and transfer host data (e.g., data received by the controller from the host) to the first memory die. The processor is configured to select a second memory die of the plurality of memory dies and perform an operation with the second memory die subsequent to transferring the write data to the first memory die and while the first memory die is in an idle state. The processor is configured to select the first memory die again and instruct the first memory die to write the transferred host data to non-volatile memory on the first memory die after performing the operations with the second memory die.

One embodiment includes a method comprising: determining that sufficient power resources exist to perform a data transfer; setting up a write operation for a first memory die to write to a first address in non-volatile memory on the first memory die and performing a data transfer to the first memory die for the write operation, in response to the determining that sufficient power resources exist to perform a data transfer; releasing the first memory die from the write operation without the first memory die writing the transferred data to the first address in non-volatile memory on the first memory die so that the first memory die is in an idle state; subsequent to the releasing, determining that sufficient power resources exist to perform the write operation; and in response to determining that sufficient power resources exist to perform the write operation, instructing the first memory die to write the transferred data to the first address in non-volatile memory on the first memory die without re-transferring the data.

One embodiment includes a memory system comprising a plurality of memory dies and a controller connected to the plurality of memory dies. The controller comprises means for managing resources in the memory system including tracking power consumption and heat dissipation in the memory system and means for arbitrating among tasks to perform. The means for arbitrating is in communication with the means for managing resources to request availability of resources from the means for managing resources. In response to availability of resources for a transfer as indicated by the means for managing resources, the means for arbitrating selects a memory die to transfer data and transfers the data to the memory die followed by releasing the memory die so that other commands can be performed without writing the data to non-volatile memory on the memory die. In response to availability of resources for a write operation as indicated by the means for managing resources, the means for arbitrating selects the memory die and commands the memory die to write the data to non-volatile memory on the memory die without re-transferring the data.

In various embodiments, the means for managing resources can be a processor programmed by software/firmware or a dedicated electrical circuit. The means for managing resources can be part of a controller (see FIGS. 1-3 and 6) or other type of control circuit for all of or a portion of a memory system or memory die (see FIGS. 1-3 and 5-6). One example of a means for managing resources includes Resource Manager 438 depicted in FIG. 6, which is a software/firmware process running on one or more of the processors of controller 102.

In various embodiments, the means for arbitrating among tasks can be a processor programmed by software/firmware or a dedicated electrical circuit. The means for managing arbitrating among tasks can be part of a controller (see FIGS. 1-3 and 6) or other type of control circuit for all of or a portion of a memory system or memory die (see FIGS. 1-3 and 5-6). One example of a means for managing resources includes Arbiter 440 depicted in FIG. 6, which is a software/firmware process running on one or more of the processors of controller 102.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus, comprising:
a first memory die; and
a controller connected to the first memory die, the controller configured to send a command to the first memory die to set up a write operation on the first memory die and transfer data for the write operation to the first memory die, the controller configured to release the first memory die from the write operation after transferring the data and without the first memory die performing the write operation so that the first memory die can process other commands, the controller configured to send a command to the first memory die to perform the write operation subsequent to releasing the first memory die from the write operation, the first memory die is configured to write the transferred data to non-volatile memory on the first memory die in response to the command to perform the write operation.

2. The apparatus of claim 1, wherein:
the first memory die includes a control circuit connected to the non-volatile memory; and
releasing the first memory die enables the control circuit to process other commands.

3. The apparatus of claim 1, wherein:
the first memory die includes a state machine and latches connected to multiple planes of flash memory, the multiple planes of flash memory are the non-volatile memory on the first memory die;
the transferring data for the write operation to the first memory die includes transferring the data from the controller to the first memory die via a Toggle Mode interface and storing the data in the latches; and
the releasing the first memory die enables the state machine to process other commands and commits the data to the latches.

4. The apparatus of claim 1, wherein:
the controller is configured to send an address for the write operation when sending the command to the first memory die to set up the write operation on the first memory die; and
the controller is configured to re-send the address for the write operation when sending the command to the first memory die to perform the write operation without re-transmitting the data.

5. The apparatus of claim 1, wherein:
the controller is configured to send the command to the first memory die to set up the write operation on the first memory die by sending a command to select the first memory die, sending a command to select number of bits per memory cell, sending a command to indicate the write operation, sending an address for the write operation, and sending a command that terminates current process; and
the controller is configured to send a command to the first memory die to perform the write operation by sending a command to select the first memory die, sending a command to select number of bits per memory cell, sending a command to indicate the write operation, sending the address for the first write operation without re-transferring the data, and sending a command to trigger the write operation.

6. The apparatus of claim 1, wherein:
the first memory die is configured to remain idle and available for processing other commands in response to being released from the write operation by the controller.

7. The apparatus of claim 1, wherein:
the controller is configured to send an additional command to the first memory die after releasing the first memory die and prior to sending the command to the first memory die to perform the write operation, performance of the additional command does not destroy the transferred data on the first memory die that has not yet been written to non-volatile memory on the first memory die.

8. The apparatus of claim 1, wherein:
the controller is configured to send an additional command to a second memory die after releasing the first memory die and prior to sending the command to the first memory die to perform the write operation, performance of the additional command does not destroy the transferred data on the first memory die that has not yet been written to non-volatile memory on the first memory die, the second memory die performs the additional command prior to the controller sending the command to the first memory die to perform the write operation.

9. The apparatus of claim 1, wherein:
the controller is configured to release the first memory die from the write operation without the first memory die performing the write operation so that the controller can perform commands with other memory dies.

10. The apparatus of claim 1, wherein:
the first memory die includes multiple planes of non-volatile memory;
the controller is configured to send a command to the first memory die to set up a write operation on the first memory die and transfer data for the write operation to the first memory die by sending an address for a first plane, transferring data for the first plane, sending an address for a second plane and transferring data for the second plane;
the controller is configured to release the first memory die from the write operation after transferring data for the first plane and transferring data for the second plane;
the controller is configured to send the command to the first memory die to perform the write operation without re-transferring data for the first plane and without re-transferring data for the second plane; and
the first memory die is configured to write to the first plane and write to the second plane response to the command to perform the write operation.

11. The apparatus of claim 1, wherein:
the first memory die includes a non-volatile memory structure comprising non-volatile memory cells that store multiple bits of data per memory cell, data is stored in the non-volatile memory structure in units of pages of data;
the controller is configured to send a command to the first memory die to set up a write operation on the first memory die and transfer data for the write operation to the first memory die by sending an address for a first page of data, transferring data for the first page, sending an address for a second page of data, and transferring data for the second page of data;
the controller is configured to release the first memory die from the write operation after transferring data for the first page of data and transferring data for the second page of data;
the controller is configured to send the command to the first memory die to perform the write operation without re-transferring data for the first page and without re-transferring data for the second page; and
the first memory die is configured to write the first page of data and write to the second page of data in response to the command to perform the write operation.

12. The apparatus of claim 1, wherein:
the controller is configured to determine that sufficient power resources are available for the transfer before transferring data for the write operation to the first memory die; and
the controller is configured to determine that sufficient power resources are available for the write operation separately from determining that sufficient power resources are available for the transfer and before sending the command to the first memory die to perform the write operation.

13. The apparatus of claim 1, wherein:
the controller is configured to determine that sufficient heat resources are available for the transfer before transferring data for the write operation to the first memory die; and
the controller is configured to determine that sufficient heat resources are available for the write operation separately from determining that sufficient heat resources are available for the transfer and before sending the command to the first memory die to perform the write operation.

14. An apparatus, comprising:
a host interface;
a memory interface; and
a processor connected to the memory interface and the host interface, the processor configured to select a first memory die of a plurality of memory dies and transfer host data to the first memory die, the processor is configured to select a second memory die of the plurality of memory dies and perform an operation with the second memory die subsequent to transferring the write data to the first memory die and while the first memory die is in an idle state, the processor is configured to select the first memory die again and instruct the first memory die to write the transferred host data to non-volatile memory on the first memory die after performing the operation with the second memory die.

15. The apparatus of claim 14, wherein:
the first memory die and the second memory die are on a common channel;
the processor is configured to release the first memory die subsequent to transferring host data to the first memory die and prior to selecting the second memory die; and
releasing the first memory die put the first memory die in the idle state such that the transferred host data is protected during the operation with the second memory die.

16. The apparatus of claim 15, wherein:
the processor is configured to determine that sufficient power resources are available for a transfer before transferring host data to the first memory die; and
the controller is configured to determine that sufficient power resources are available for a write operation separately from determining that sufficient power resources are available for a transfer and before instructing the first memory die to write the transferred host data.

17. A method comprising:
determining that sufficient power resources exist to perform a data transfer;
setting up a write operation for a first memory die to write to a first address in non-volatile memory on the first memory die and performing a data transfer to the first memory die for the write operation, in response to the determining that sufficient power resources exist to perform a data transfer;
releasing the first memory die from the write operation without the first memory die writing the transferred data to the first address in non-volatile memory on the first memory die so that the first memory die is in an idle state;
subsequent to the releasing, determining that sufficient power resources exist to perform the write operation; and
in response to determining that sufficient power resources exist to perform a write operation, instructing the first memory die to write the transferred data to the first address in non-volatile memory on the first memory die without re-transferring the data.

18. The method of claim 17, wherein:
after releasing the first memory die from the write operation and prior to instructing the first memory die to write the transferred data, performing additional operations on the first memory die without damaging the data transferred to the first memory die for the write operation.

19. The method of claim 17, wherein:
after releasing the first memory die from the write operation and prior to instructing the first memory die to write the transferred data, performing additional operations on the another memory die without damaging the data transferred to the first memory die for the write operation.

20. The method of claim 17, wherein:
the first memory die stores multiple bits of data per memory cell in multiple pages per memory cell; and
the step of releasing is performed after data has been transferred for all of the multiple pages per memory cell.

21. A memory system, comprising:
a plurality of memory dies; and
a controller connected to the plurality of memory dies, the controller comprises:
means for managing resources in the memory system including tracking power consumption and heat dissipation in the memory system, and
means for arbitrating among tasks to perform, the means for arbitrating is in communication with the means for managing resources to request availability of resources from the means for managing resources, in response to availability of resources for a transfer as indicated by the means for managing resources the means for arbitrating selects a memory die to transfer data and transfers the data to the memory die followed by releasing the memory die so that other commands can be performed without writing the data to non-volatile memory on the memory die, in response to availability of resources for a write operation as indicated by the means for managing resources the means for arbitrating selects the memory die and commands the memory die to write the data to non-volatile memory on the memory die without re-transferring the data.
